(19) United States
(12) Patent Application Publication
(10) Pub. No.: US 2024/0117220 A1
(43) Pub. Date: Apr. 11, 2024

(54) CHEMICAL-MECHANICAL POLISHING COMPOSITION FOR HEAVILY-DOPED BORON SILICON FILMS

(71) Applicant: CMC Materials LLC, Aurora, IL (US)

(72) Inventors: Alex Villani-Gale, Chicago, IL (US); Elliot Knapton, Aurora, IL (US); Brian Reiss, Woodridge, IL (US)

(21) Appl. No.: 18/378,111

(22) Filed: Oct. 9, 2023

Related U.S. Application Data
(60) Provisional application No. 63/415,148, filed on Oct. 11, 2022.

(51) Int. Cl. C09G 1/02; C09K 13/00; H01L 21/306

(52) U.S. Cl. CPC C09G 1/02; C09K 13/00; H01L 21/30625

(57) ABSTRACT

The invention provides a chemical-mechanical polishing composition comprising: (a) a silica abrasive; (b) an oxidizing agent; and (c) water, wherein the chemical-mechanical polishing composition has a pH of about 2 or less. The invention also provides a method of chemically-mechanically polishing a substrate, especially a substrate comprising a boron-doped polysilicon layer on a surface of the substrate, using said composition.

### BACKGROUND OF THE INVENTION

Compositions and methods for planarizing or polishing the surface of a substrate are well known in the art. Polishing compositions (also known as polishing slurries) typically contain an abrasive material in a liquid carrier and are applied to a surface by contacting the surface with a polishing pad saturated with the polishing composition. Typical abrasive materials include silicon dioxide, cerium oxide, aluminum oxide, zirconium oxide, and tin oxide. Polishing compositions typically are used in conjunction with polishing pads (e.g., a polishing cloth or disk). The abrasive material may be incorporated into the polishing pad instead of, or in addition to, being suspended in the polishing composition.

Boron-doped polysilicon or boron-polysilicon alloys are increasingly being employed as a patterning hard mask during the fabrication of advanced node memory devices, such as dynamic random access memory (DRAM). It can be challenging to achieve a high removal rate of this material by chemical-mechanical planarization (CMP) due to the high levels of boron in the polysilicon material. In addition to requiring a high removal rate of the boron-polysilicon film, some memory device schemes also require very low removal rates for silicon nitride and/or silicon oxide, which could serve as stopping layers in the device film stack. This presents a selectivity requirement during CMP. In addition, titanium nitride also is used in the fabrication of some memory devices. The ability to tune the relative removal rate of titanium nitride would be a desirable feature for polishing compositions and methods useful in the fabrication of the devices.

Thus, there remains a need in the art for polishing compositions and methods for polishing boron-polysilicon layers with high removal rates and selectivity for the boron-polysilicon.

### BRIEF SUMMARY OF THE INVENTION

The invention provides a chemical-mechanical polishing composition comprising: (a) a silica abrasive; (b) an oxidizing agent; and (c) water, wherein the chemical-mechanical polishing composition has a pH of about 2 or less.

The invention further provides a method of chemically-mechanically polishing a substrate comprising: (i) providing a substrate, (ii) providing a polishing pad, (iii) providing a chemical-mechanical polishing composition comprising: (a) a silica abrasive; (b) an oxidizing agent; and (c) water, wherein the chemical-mechanical polishing composition has a pH of about 2 or less, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

### BRIEF DESCRIPTION OF THE DRAWINGS

FIG. 1 shows the boron-polysilicon (BSi) removal rate (Å/min) vs. polishing composition, as described in Example 1.

FIG. 2 shows the tetraethyl orthosilicate (TEOS) removal rate (Å/min) vs. polishing composition, as described in Example 1.

FIG. 3 shows the boron-polysilicon (BSi) removal rate (Å/min) vs. particle size exhibited by a polishing composition comprising cerium ammonium nitrate (CAN), as described in Example 2.

FIG. 4 shows the tetraethyl orthosilicate (TEOS) removal rate (Å/min) vs. particle size exhibited by a polishing composition comprising cerium ammonium nitrate (CAN), as described in Example 2.

FIG. 5 shows the boron-polysilicon (BSi) removal rate (Å/min) vs. particle type exhibited by a polishing composition comprising cerium ammonium nitrate (CAN), as described in Example 3.

FIG. 6 shows the tetraethyl orthosilicate (TEOS) removal rate (Å/min) vs. particle type exhibited by a polishing composition comprising cerium ammonium nitrate (CAN), as described in Example 3.

### DETAILED DESCRIPTION OF THE INVENTION

The invention provides a chemical-mechanical polishing composition comprising: (a) a silica abrasive; (b) an oxidizing agent; and (c) water, wherein the chemical-mechanical polishing composition has a pH of about 2 or less.

The polishing composition comprises an abrasive. As used herein, the terms “abrasive” and “abrasive particle” can be used interchangeably, and can refer to any dispersion of abrasive particles. In other words the terms “abrasive” and “abrasive particle” can be used interchangeably, and can refer to (i) a plurality of a single type of abrasive or abrasive particle and/or (ii) a plurality of more than one type of abrasive or abrasive particle.

The polishing composition comprises a silica abrasive. As used herein, the terms “silica abrasive,” “silica abrasive particle,” “silica particle,” and “abrasive particle” can be used interchangeably, and can refer to any silica particle (e.g., colloidal silica particle). The silica particle (e.g., colloidal silica particle) can be modified (e.g., surface modified) or unmodified, and have a negative zeta potential, a neutral zeta potential, or a positive zeta potential.

The charge on dispersed particles such as a silica abrasive (e.g., colloidal silica particles) is commonly referred to as the zeta potential (or the electrokinetic potential). The zeta potential of a particle refers to the electrical potential difference between the electrical charge of the ions surrounding the particle and the electrical charge of the bulk solution of the composition in which it is measured (e.g., the liquid carrier and any other components dissolved therein). The zeta potential is typically dependent on the pH of the aqueous medium. For a given polishing composition, the isoelectric point of the particles is defined as the pH at which the zeta potential is zero. As the pH is increased or decreased away from the isoelectric point, the surface charge (and hence the zeta potential) is correspondingly decreased or increased (to negative or positive zeta potential values, respectively). As used herein, the phrase “negative zeta potential” refers to a silica abrasive that exhibits a negative surface charge when measured in the polishing composition. As used herein, the phrase “neutral zeta potential” refers to a silica abrasive that exhibits a net zero surface charge when measured in the polishing composition. As used herein, the phase “positive zeta potential” refers to a silica abrasive that exhibits a positive surface charge when measured in the polishing composition.

The silica particle (e.g., colloidal silica particle) can have a negative native zeta potential, a neutral native zeta potential, or a positive native zeta potential. As used herein, the phrase “native zeta potential” refers to the zeta potential of the silica abrasive prior to adding the silica abrasive to the polishing composition. For example, the native zeta potential can refer to the zeta potential of a silica abrasive prior to adding the silica abrasive to the polishing composition as measured in a storage solution or an aqueous solution. A skilled artisan will be able to determine whether the silica abrasive, prior to adding the silica abrasive to the polishing composition, has a negative native zeta potential, a neutral native zeta potential, or a positive native zeta potential.

The native zeta potential and the zeta potential of the polishing composition may be obtained using the Model DT-1202 Acoustic and Electro-acoustic spectrometer available from Dispersion Technologies, Inc. (Bedford Hills, N.Y.).

The silica abrasive (e.g., colloidal silica particle) can be modified (e.g., surface modified) or unmodified, and have a negative native zeta potential, a neutral native zeta potential, or a positive native zeta potential. Thus, the silica abrasive (e.g., colloidal silica particle) can have a positive zeta potential, neutral zeta potential, or a negative zeta potential prior to addition to the chemical-mechanical polishing composition. For example, the silica particle (e.g., colloidal silica particle) can have a native zeta potential of less than 0 mV (e.g., −5 mV, or lower) prior to addition to the chemical-mechanical polishing composition, i.e., a negative native zeta potential. Alternatively, the silica particle (e.g., colloidal silica particle) can have a native zeta potential of 0 mV or more (e.g., 5 mV, or more) prior to addition to the chemical-mechanical polishing composition, i.e., a positive native zeta potential. In other embodiments, the silica particle (e.g., colloidal silica particle) has a native zeta potential of about 0 mV, i.e., a neutral native zeta potential.

Silica particles (e.g., colloidal silica particles) and charged silica particles (e.g., colloidal silica particles) can be prepared by various methods, some examples of which are commercially used and known. Useful silica particles include precipitated or condensation-polymerized silica, which may be prepared using known methods, such as by methods referred to as “sol gel” methods or by silicate ion-exchange. Condensation-polymerized silica particles are often prepared by condensing Si(OH)₄ to form substantially spherical (e.g., spherical, ovular, or oblong) particles. The precursor Si(OH)₄ may be obtained, for example, by hydrolysis of high purity alkoxysilanes, or by acidification of aqueous silicate solutions. U.S. Pat. No. 5,230,833 describes a method for preparing colloidal silica particles in solution.

In some embodiments, the silica abrasive is colloidal silica. As known to one of ordinary skill in the art, colloidal silicas are suspensions of fine amorphous, nonporous and typically spherical particles in a liquid phase. The colloidal silica can take the form of condensation-polymerized or precipitated silica particles. In some embodiments, the silica is in the form of wet-process type silica particles. The particles, e.g., colloidal silica, can have any suitable average size (i.e., average particle diameter). If the average abrasive particle size is too small, the polishing composition may not exhibit sufficient removal rate. In contrast, if the average abrasive particle size is too large, the polishing composition may exhibit undesirable polishing performance such as, for example, poor substrate defectivity.

Accordingly, the silica abrasive (e.g., silica particles or colloidal silica particles) can have an average particle size of about 10 nm or more, for example, about 15 nm or more, about 20 nm or more, about 25 nm or more, about 30 nm or more, about 35 nm or more, about 40 nm or more, about 45 nm or more, or about 50 nm or more. Alternatively, or in addition, the silica abrasive can have an average particle size of about 200 nm or less, for example, about 175 nm or less, about 150 nm or less, about 125 nm or less, about 100 nm or less, about 75 nm or less, about 50 nm or less, or about 40 nm or less. Thus, the silica abrasive can have an average particle size bounded by any two of the aforementioned endpoints.

For example, the silica abrasive (e.g., silica particles or colloidal silica particles) can have an average particle size of about 10 nm to about 200 nm, about 20 nm to about 200 nm, about 20 nm to about 175 nm, about 20 nm to about 150 nm, about 25 nm to about 125 nm, about 25 nm to about 100 nm, about 30 nm to about 100 nm, about 30 nm to about 75 nm, about 30 nm to about 40 nm, or about 50 nm to about 100 nm. For non-spherical silica abrasive particles, the size of the particle is the diameter of the smallest sphere that encompasses the particle. In some embodiments, the silica abrasive has an average particle size of about 25 nm to about 100 nm. In certain embodiments, the silica abrasive has an average particle size of about 30 nm to about 75 nm. Without wishing to be bound by any particular theory, it is believed that a smaller abrasive particle (e.g., less than about 100 nm) provides a lower silicon oxide (e.g., TEOS) removal rate, and, thus, better selectivity for boron-polysilicon. The particle size of the abrasive can be measured using any suitable technique, for example, using laser diffraction techniques. Suitable particle size measurement instruments are available from e.g., Malvern Instruments (Malvern, UK).

The silica abrasive (e.g., silica particles or colloidal silica particles) preferably are colloidally stable in the polishing composition. The term colloid refers to the suspension of particles in the liquid carrier (e.g., water). Colloidal stability refers to the maintenance of that suspension through time. In the context of this invention, an abrasive is considered colloidally stable if, when the abrasive is placed into a 100 mL graduated cylinder and allowed to stand unagitated for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., {[B]−[T]}/[C]≤0.5). More preferably, the value of [B]−[T]/[C] is less than or equal to 0.3, and most preferably is less than or equal to 0.1.

The silica abrasive can be present in the polishing composition in any suitable amount. If the polishing composition of the invention comprises too little abrasive, the composition may not exhibit sufficient removal rate. In contrast, if the polishing composition comprises too much abrasive, the polishing composition may exhibit undesirable polishing performance and/or may not be cost effective and/or may lack stability. The polishing composition can comprise about 10 wt. % or less of the silica abrasive, for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the silica abrasive. Alternatively, or in addition, the polishing composition can comprise about 0.001 wt. % or more of the silica abrasive, for example, about 0.005 wt. % or more, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of silica abrasive. Thus, the polishing composition can comprise silica abrasive in any amount bounded by any two of the aforementioned endpoints, as appropriate.

For example, in some embodiments, the silica abrasive can be present in the polishing composition in an amount of about 0.001 wt. % to about 10 wt. % of the polishing composition, e.g., about 0.001 wt. % to about 8 wt. %, about 0.001 wt. % to about 6 wt. %, about 0.001 wt. % to about 5 wt. %, about 0.001 wt. % to about 4 wt. %, about 0.001 wt. % to about 2 wt. %, about 0.001 wt. % to about 1 wt. %, about 0.001 wt. % to about 0.05 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.025 wt. % to about 10 wt. %, about 0.025 wt. % to about 8 wt. %, about 0.025 wt. % to about 6 wt. %, about 0.025 wt. % to about 5 wt. %, about 0.025 wt. % to about 4 wt. %, about 0.025 wt. % to about 2 wt. %, about 0.025 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 10 wt. %, about 0.5 wt. % to about 8 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 10 wt. %, about 1 wt. % to about 8 wt. %, about 1 wt. % to about 6 wt. %, about 1 wt. % to about 5 wt. %, about 1 wt. % to about 4 wt. %, or about 1 wt. % to about 2 wt. %. In some embodiments, the polishing composition comprises about 0.001 wt. % to about 10 wt. % of the silica abrasive. In certain embodiments, the polishing composition comprises about 0.05 wt. % to about 5 wt. % of the silica abrasive. In other embodiments, the polishing composition comprises about 0.001 wt. % to about 0.05 wt. % of the silica abrasive.

The chemical-mechanical polishing composition comprises an oxidizing agent. The oxidizing agent can be any suitable compound capable of oxidizing a substrate (e.g., boron-doped polysilicon, silicon nitride, silicon oxide, or titanium nitride). For example, the oxidizing agent can be selected from oxone, cerium ammonium nitrate, a peroxide (e.g., hydrogen peroxide), a periodate (e.g., sodium periodate or potassium periodate), an iodate (e.g., sodium iodate, potassium iodate, or ammonium iodate), a persulfate (e.g., sodium persulfate, potassium persulfate, or ammonium persulfate), a chlorate (e.g., sodium chlorate or potassium chlorate), a chromate (e.g., sodium chromate or potassium chromate), a permanganate (e.g., sodium permanganate, potassium permanganate, or ammonium permanganate), a bromate (e.g., sodium bromate or potassium bromate), a perbromate (e.g., sodium perbromate or potassium perbromate), a ferrate (e.g., potassium ferrate), a perrhenate (e.g., ammonium perrhenate), a perruthenate (e.g., tetrapropylammonium perruthenate), and a combination thereof. The oxidizing agent can be in acid form (e.g., persulfuric acid), salt form (e.g., ammonium persulfate), or a mixture thereof. In some embodiments, the oxidizing agent comprises the alkali metal (e.g., sodium or potassium) salt of a peroxide, a periodate, an iodate, a persulfate, a chlorate, a chromate, a permanganate, a bromate, a perbromate, a ferrate, a perrhenate, a perruthenate, or combinations thereof.

In certain embodiments, the oxidizing agent is selected from a permanganate (e.g., sodium permanganate, potassium permanganate, or ammonium permanganate), cerium ammonium nitrate, and a combination thereof. In some embodiments the oxidizing agent is cerium ammonium nitrate. In other embodiments, the oxidizing agent is a permanganate (e.g., sodium permanganate, potassium permanganate, or ammonium permanganate) such as potassium permanganate.

The polishing composition can comprise any suitable amount of the oxidizing agent. The polishing composition can comprise about 20 wt. % or less of the oxidizing agent, for example, about 15 wt. % or less, about 10 wt. % or less, about 9 wt. % or less, about 8 wt. % or less, about 7 wt. % or less, about 6 wt. % or less, about 5 wt. % or less, about 4 wt. % or less, about 3 wt. % or less, or about 2 wt. % or less of the oxidizing agent. Alternatively, or in addition, the polishing composition can comprise about 0.1 wt. % or more of the oxidizing agent, for example, about 0.5 wt. % or more, about 1 wt. % or more, about 2 wt. % or more, about 3 wt. % or more, about 4 wt. % or more, or about 5 wt. % or more of the oxidizing agent. Thus, the polishing composition can comprise the oxidizing agent in any amount bounded by any two of the aforementioned endpoints, as appropriate.

For example, in some embodiments, the oxidizing agent can be present in the polishing composition in an amount of about 0.1 wt. % to about 20 wt. %, about 0.1 wt. % to about 15 wt. %, about 0.1 wt. % to about 10 wt. %, about 0.1 wt. % to about 9 wt. %, about 0.1 wt. % to about 8 wt. %, about 0.1 wt. % to about 7 wt. %, about 0.1 wt. % to about 6 wt. %, about 0.1 wt. % to about 5 wt. %, about 0.1 wt. % to about 4 wt. %, about 0.1 wt. % to about 3 wt. %, about 0.1 wt. % to about 2 wt. %, about 0.5 wt. % to about 20 wt. %, about 0.5 wt. % to about 15 wt. %, about 0.5 wt. % to about 10 wt. %, about 0.5 wt. % to about 9 wt. %, about 0.5 wt. % to about 8 wt. %, about 0.5 wt. % to about 7 wt. %, about 0.5 wt. % to about 6 wt. %, about 0.5 wt. % to about 5 wt. %, about 0.5 wt. % to about 4 wt. %, about 0.5 wt. % to about 3 wt. %, about 0.5 wt. % to about 2 wt. %, about 1 wt. % to about 20 wt. %, about 1 wt. % to about 15 wt. %, about 1 wt. % to about 10 wt. %, about 1 wt. % to about 9 wt. %, about 1 wt. % to about 8 wt. %, about 1 wt. % to about 7 wt. %, about 1 wt. % to about 6 wt. %, about 1 wt. % to about 5 wt. %, about 1 wt. % to about 4 wt. %, about 1 wt. % to about 3 wt. %, about 1 wt. % to about 2 wt. %, about 2 wt. % to about 20 wt. %, about 2 wt. % to about 15 wt. %, about 2 wt. % to about 10 wt. %, about 2 wt. % to about 9 wt. %, about 2 wt. % to about 8 wt. %, about 2 wt. % to about 7 wt. %, about 2 wt. % to about 6 wt. %, about 2 wt. % to about 5 wt. %, about 2 wt. % to about 4 wt. %, about 2 wt. % to about 3 wt. %, about 3 wt. % to about 20 wt. %, about 3 wt. % to about 15 wt. %, about 3 wt. % to about 10 wt. %, about 3 wt. % to about 9 wt. %, about 3 wt. % to about 8 wt. %, about 3 wt. % to about 7 wt. %, about 3 wt. % to about 6 wt. %, about 3 wt. % to about 5 wt. %, or about 3 wt. % to about 4 wt. %. In some embodiments, the polishing composition comprises at least 1 wt. % of the oxidizing agent, at least 2 wt. % of the oxidizing agent, or at least 3 wt. % of the oxidizing agent.

The polishing composition can comprise ferric ion, cobalt ion, manganese ion, an organic acid, or combinations thereof.

The ferric ion can be provided in the form of any suitable ferric salt. A non-limiting example of a suitable ferric salt is ferric nitrate. The polishing composition can comprise any suitable amount of ferric ion. For example, the polishing composition can comprise about 0.005 wt. % to about 1 wt. % of ferric ion, for example, about 0.01 wt. % to about 0.9 wt. %, about 0.02 wt. % to about 0.8 wt. %, about 0.03 wt. % to about 0.6 wt. %, about 0.03 wt. % to about 0.4 wt. %, about 0.03 wt. % to about 0.2 wt. %, or about 0.03 wt. % to about 0.1 wt. % of ferric ion.

In some embodiments, the polishing composition comprises substantially no ferric ion. In the context of the present invention, “substantially no ferric ion” means that the polishing composition comprises about 0.01 wt. % or less of ferric ion, e.g., about 0.005 wt. % or less, about 0.001 wt. % or less, or about 0.0001 wt. % or less, or that no ferric ion can be detected in the polishing composition.

The cobalt ion can be provided in the form of any suitable cobalt salt. A non-limiting example of a suitable cobalt salt is cobalt acetate. The polishing composition can comprise any suitable amount of cobalt ion. For example, the polishing composition can comprise about 0.005 wt. % to about 1 wt. % of cobalt ion, e.g., about 0.01 wt. % to about 0.9 wt. %, about 0.02 wt. % to about 0.8 wt. %, about 0.03 wt. % to about 0.6 wt. %, about 0.03 wt. % to about 0.4 wt. %, about 0.03 wt. % to about 0.2 wt. %, or about 0.03 wt. % to about 0.1 wt. % of cobalt ion.

In some embodiments, the polishing composition comprises substantially no cobalt ion. In the context of the present invention, “substantially no cobalt ion” means that the polishing composition comprises about 0.01 wt. % or less of cobalt ion, e.g., about 0.005 wt. % or less, about 0.001 wt. % or less, or about 0.0001 wt. % or less, or that no cobalt ion can be detected in the polishing composition.

The manganese ion can be provided in the form of any suitable manganese salt. A non-limiting example of a suitable manganese salt is manganese acetate. The polishing composition can comprise any suitable amount of manganese ion. For example, the polishing composition can comprise about 0.005 wt. % to about 1 wt. % of manganese ion, for example, about 0.01 wt. % to about 0.9 wt. %, about 0.02 wt. % to about 0.8 wt. %, about 0.03 wt. % to about 0.6 wt. %, about 0.03 wt. % to about 0.4 wt. %, about 0.03 wt. % to about 0.2 wt. %, or about 0.03 wt. % to about 0.1 wt. % of manganese ion.

In some embodiments, the polishing composition comprises substantially no manganese ion. In the context of the present invention, “substantially no manganese ion” means that the polishing composition comprises about 0.01 wt. % or less of manganese ion, e.g., about 0.005 wt. % or less, about 0.001 wt. % or less, or about 0.0001 wt. % or less, or that no manganese ion can be detected in the polishing composition.

The polishing composition can comprise an organic acid. The organic acid can be any suitable organic acid. Non-limiting examples of suitable organic acids include tartaric acid, lactic acid, formic acid, acetic acid, maleic acid, L-ascorbic acid, picolinic acid, and malonic acid. In some embodiments, the organic acid is selected from maleic acid, L-ascorbic acid, picolinic acid, malonic acid, and a combination thereof.

The polishing composition can comprise the organic acid at any suitable concentration. For example, the polishing composition can comprise about 1 mM or more of the organic acid, e.g., about 2 mM or more, about 3 mM or more, about 4 mM or more, or about 5 mM or more. Alternatively, or in addition, the polishing composition can comprise about 100 mM or less of the organic acid, e.g., about 50 mM or less, about 25 mM or less, about 20 mM or less, about 19 mM or less, about 18 mM or less, about 17 mM or less, about 16 mM or less, or about 15 mM or less. Thus, the polishing composition can comprise the organic acid in any amount bounded by any two of the aforementioned endpoints. For example, the polishing composition can comprise about 1 mM to about 20 mM of the organic acid, e.g., about 1 mM to about 15 mM, about 2 mM to about 15 mM, about 3 mM to about 15 mM, about 3 mM to about 12 mM, about 1 mM to about 12 mM, or about 1 mM to about 10 mM. In some embodiments, the polishing composition comprises about 1 mM to about 100 mM of the organic acid.

In some embodiments, the polishing composition comprises substantially no organic acid. In the context of the present invention, “substantially no organic acid” means that the polishing composition comprises about 1 mM or less of ferric ion, e.g., about 0.5 mM or less, about 1 μM or less, or about 0.5 μM or less, or that no organic acid can be detected in the polishing composition. In certain embodiments, the polishing composition comprises substantially no ferric ion, substantially no cobalt ion, substantially no manganese ion, and/or substantially no organic acid.

The polishing composition comprises water. The water can be any suitable water and can be, for example, deionized water or distilled water. In some embodiments, the polishing composition can further comprise one or more organic solvents in combination with the water. For example, the polishing composition can further comprise a hydroxylic solvent such as methanol or ethanol, a ketonic solvent, an amide solvent, a sulfoxide solvent, and the like.

The polishing composition can have any suitable pH. Typically, the polishing composition has a pH of about 2 or less, e.g., about 1.8 or less, about 1.6 or less, about 1.5 or less, about 1.4 or less, about 1.2 or less, about 1 or less, about 0.8 or less, about 0.6 or less, or about 0.5 or less. Alternatively, or in addition, the polishing composition can have a pH of about −2 or more, e.g., about −1.5 or more, about −1 or more, about 0.5 or more, about 0 or more, about 0.2 or more, about 0.4 or more, or about 0.5 or more. Thus, the polishing composition can have a pH bounded by any two of the aforementioned endpoints. For example, the polishing composition can have a pH of about −2 to about 2, e.g., about −1.5 to about 2, about −1 to about 2, about −0.5 to about 2, about 0 to about 2, about 0.2 to about 2, about 0.4 to about 2, about 0.5 to about 2, about −2 to about 1.8, about −1.5 to about 1.8, about −1 to about 1.8, about −0.5 to about 1.8, about 0 to about 1.8, about 0.2 to about 1.8, about 0.4 to about 1.8, about 0.5 to about 1.8, about −2 to about 1.5, about −1.5 to about 1.5, about −1 to about 1.5, about −0.5 to about 1.5, about 0 to about 1.5, about 0.2 to about 1.5, about 0.4 to about 1.5, about 0.5 to about 1.5, about −2 to about 1, about −1.5 to about 1, about −1 to about 1, about −0.5 to about 1, about 0 to about 1, about 0.2 to about 1, about 0.4 to about 1, or about 0.5 to about 1. In some embodiments, the chemical-mechanical polishing composition has a pH of about 2 or less. In certain embodiments, the polishing composition has a pH of about 1.5 or less or a pH of about 1 or less. In other embodiments, the polishing composition has a pH of about 0 to about 2 or a pH of about 0 to about 1.5.

The pH of the polishing composition can be adjusted using any suitable acid or base. Non-limiting examples of suitable acids include nitric acid, sulfuric acid, phosphoric acid, and organic acids such as formic acid and acetic acid. Non-limiting examples of suitable bases include sodium hydroxide, potassium hydroxide, and ammonium hydroxide.

In some embodiments, the polishing composition further comprises a buffering agent. The buffering agent can be any suitable compound capable of buffering (e.g., maintaining) the polishing composition at a particular pH range. For example, the buffering agent can be selected from an ammonium salt, an alkali metal salt, an alkali metal hydroxide, an alkali metal carbonate, an alkali metal bicarbonate, a borate, an amino acid, and a combination thereof.

The chemical-mechanical polishing composition optionally further comprises one or more additives. Illustrative additives include conditioners, acids (e.g., sulfonic acids), complexing agents, chelating agents, biocides, scale inhibitors, and dispersants.

In some embodiments, the polishing composition further comprises a biocide. A non-limiting example of a suitable biocide is an isothiazolinone based biocide such as Kordek MLX™ (DuPont, Wilmington, DE). The polishing composition can comprise any suitable amount of the biocide. For example, the polishing composition can comprise about 0.001 wt. % to about 0.2 wt. % of the biocide.

In some embodiments, the invention provides a chemical-mechanical polishing composition comprising, consisting essentially of, or consisting of: (a) a silica abrasive; (b) at least 1 wt. % of a permanganate (e.g., potassium permanganate); and (c) water, wherein the chemical-mechanical polishing composition has a pH of about 2 or less.

In other embodiments, the invention provides a chemical-mechanical polishing composition comprising, consisting essentially of, or consisting of: (a) a silica abrasive; (b) at least 1 wt. % of cerium ammonium nitrate; and (c) water, wherein the chemical-mechanical polishing composition has a pH of about 2 or less.

The polishing composition can be produced by any suitable technique, many of which are known to those skilled in the art. The polishing composition can be prepared in a batch or continuous process. Generally, the polishing composition is prepared by combining the components of the polishing composition. The term “component” as used herein includes individual ingredients (e.g., silica abrasive, oxidizing agent, optional pH adjustor, and/or any optional additive) as well as any combination of ingredients (e.g., silica abrasive, oxidizing agent, optional pH adjustor, and/or any optional additive, etc.).

For example, the polishing composition can be prepared by (i) providing all or a portion of the liquid carrier, (ii) dispersing the silica abrasive, oxidizing agent, optional pH adjustor, and/or any optional additive, using any suitable means for preparing such a dispersion, (iii) adjusting the pH of the dispersion as appropriate, and (iv) optionally adding suitable amounts of any other optional components and/or additives to the mixture.

Alternatively, the polishing composition can be prepared by (i) providing one or more components (e.g., oxidizing agent, optional pH adjustor, and/or any optional additive) in a silica abrasive slurry, (ii) providing one or more components in an additive solution (e.g., liquid carrier, oxidizing agent, optional pH adjustor, and/or any optional additive), (iii) combining the silica abrasive slurry and the additive solution to form a mixture, (iv) optionally adding suitable amounts of any other optional additives to the mixture, and (v) adjusting the pH of the mixture as appropriate.

The polishing composition can be supplied as a one-package system comprising a silica abrasive, oxidizing agent, optional pH adjustor, and/or any optional additive, and water. Alternatively, the polishing composition of the invention can be supplied as a two-package system comprising a silica abrasive slurry in a first package and an additive solution in a second package, wherein the silica abrasive slurry consists essentially of, or consists of, a silica abrasive, and water, and wherein the additive solution consists essentially of, or consists of, oxidizing agent, optional pH adjustor, and/or any optional additive. The two-package system allows for the adjustment of polishing composition characteristics by changing the blending ratio of the two packages, i.e., the silica abrasive slurry and the additive solution.

Various methods can be employed to utilize such a two-package polishing system. For example, the silica abrasive slurry and additive solution can be delivered to the polishing table by different pipes that are joined and connected at the outlet of supply piping. The silica abrasive slurry and additive solution can be mixed shortly or immediately before polishing, or can be supplied simultaneously on the polishing table. Furthermore, when mixing the two packages, deionized water can be added, as desired, to adjust the polishing composition and resulting substrate polishing characteristics.

Similarly, a three-, four-, or more package system can be utilized in connection with the invention, wherein each of multiple containers contains different components of the inventive chemical-mechanical polishing composition, one or more optional components, and/or one or more of the same components in different concentrations.

In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use” if the components are combined about 5 minutes or less prior to being added in mixed form onto the platen, for example, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 m of the point-of-use, such as within 1 m of the point-of-use or even within 10 cm of the point-of-use (e.g., within 1 cm of the point-of-use).

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the silica abrasive, oxidizing agent, optional pH adjustor, and/or any optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component. Furthermore, as will be understood by those of ordinary skill in the art, the concentrate can contain an appropriate fraction of the water present in the final polishing composition in order to ensure that the silica abrasive, oxidizing agent, optional pH adjustor, and/or any optional additive are at least partially or fully dissolved in the concentrate.

The invention further provides a method of chemically-mechanically polishing a substrate comprising: (i) providing a substrate, (ii) providing a polishing pad, (iii) providing a chemical-mechanical polishing composition comprising: (a) a silica abrasive; (b) an oxidizing agent; and (c) water, wherein the chemical-mechanical polishing composition has a pH of about 2 or less, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The substrate can be any suitable substrate. In certain embodiments, the substrate comprises boron-doped polysilicon such as, for example, boron-polysilicon alloys. Thus, the method may include a substrate comprising a boron-doped polysilicon layer on a surface of the substrate, and wherein at least a portion of the boron-doped polysilicon layer on a surface of the substrate is abraded to polish the substrate. Alternatively, or additionally, the substrate may comprise a silicon nitride layer on a surface of the substrate, a silicon oxide layer on a surface of the substrate, a titanium nitride layer on a surface of the substrate, or combinations thereof. For example, the method may include a substrate comprising (i) a silicon nitride layer on a surface of the substrate, and wherein at least a portion of the silicon nitride layer on the surface of the substrate is abraded to polish the substrate (ii) a silicon oxide layer on a surface of the substrate, and wherein at least a portion of the silicon oxide layer on a surface of the substrate is abraded to polish the substrate, and/or (iii) a titanium nitride layer on a surface of the substrate, and wherein at least a portion of the titanium nitride layer on a surface of the substrate is abraded to polish the substrate. In certain embodiments, the substrate comprises a boron-doped polysilicon layer on a surface of the substrate in combination with silicon oxide layer, a silicon nitride layer, and/or a titanium nitride layer on the surface of the substrate.

The boron-doped polysilicon can be any suitable boron-doped polysilicon, many of which are known in the art. The polysilicon can have any suitable phase and can be amorphous, crystalline, or a combination thereof. The level of boron doping can be any suitable level. Generally, the boron-doped polysilicon layer comprises at least 75 wt. % boron, at least 80 wt. % boron, at least 85 wt. % boron, or at least 90 wt. % boron. For example, the boron-doped polysilicon layer can comprise about 75 wt. % to about 99.9 wt. % boron, e.g., 75 wt. % to about 99 wt. %, about 75 wt. % to about 95 wt. %, about 75 wt. % to about 90 wt. %, about 80 wt. % to about 99.9 wt. %, about 80 wt. % to about 99 wt. %, about 80 wt. % to about 95 wt. %, about 80 wt. % to about 90 wt. %, about 85 wt. % to about 99.9 wt. %, about 85 wt. % to about 99 wt. %, about 85 wt. % to about 95 wt. %, about 85 wt. % to about 90 wt. %, about 90 wt. % to about 99.9 wt. %, about 90 wt. % to about 99 wt. %, about 90 wt. % to about 95 wt. %, about 95 wt. % to about 99.9 wt. %, or about 95 wt. % to about 99 wt. %. Without wishing to about bound by any particular theory, it is believed that the compositions and methods provided herein are particularly suitable for polishing boron-doped polysilicon with high levels (e.g., about 75 wt. % or more, about 80 wt. % or more, about 85 wt. % or more, or about 90 wt. % or more) of boron doping.

The polishing composition of the invention desirably exhibits a high removal rate when polishing a substrate comprising boron-doped polysilicon according to a method of the invention. For example, when polishing silicon wafers comprising boron-doped polysilicon layers in accordance with an embodiment of the invention, the polishing composition desirably exhibits a removal rate of the boron-doped polysilicon of about 500 Å/min or higher, e.g., about 550 Å/min or higher, about 600 Å/min or higher, about 650 Å/min or higher, about 700 Å/min or higher, about 750 Å/min or higher, about 800 Å/min or higher, about 850 Å/min or higher, about 900 Å/min or higher, about 950 Å/min or higher, about 1000 Å/min or higher, about 1100 Å/min or higher, about 1200 Å/min or higher, about 1300 Å/min or higher, about 1400 Å/min or higher, about 1500 Å/min or higher, about 1600 Å/min or higher, about 1700 Å/min or higher, about 1800 Å/min or higher, about 1900 Å/min or higher, about 2000 Å/min or higher, about 2100 Å/min or higher, about 2200 Å/min or higher, about 2300 Å/min or higher, about 2400 Å/min or higher, about 2500 Å/min or higher, about 2600 Å/min or higher, about 2700 Å/min or higher, about 2800 Å/min or higher, about 2900 Å/min or higher, or about 3000 Å/min or higher.

In some embodiments, where the substrate further comprises silicon oxide, the silicon oxide can be any suitable silicon oxide, many of which are known in the art. Suitable types of silicon oxide include but are not limited to borophosphosilicate glass (BPSG), tetraethyl orthosilicate (TEOS), plasma enhanced tetraethylorthosilicate (PETEOS), thermal oxide, undoped silicate glass, and high density plasma (HDP) oxide. The chemical-mechanical polishing composition of the invention desirably exhibits a low removal rate of silicon oxide when polishing a substrate comprising silicon oxide according to a method of the invention. For example, when polishing substrates comprising silicon oxide in accordance with an embodiment of the invention, the polishing composition desirably exhibits a removal rate of silicon oxide of about 500 Å/min or lower, e.g., about 250 Å/min or lower, about 200 Å/min or lower, about 150 Å/min or lower, about 100 Å/min or lower, about 50 Å/min or lower, about 25 Å/min or lower, about 10 Å/min or lower, or about 5 Å/min or lower. In some embodiments, the polishing composition exhibits a silicon oxide removal rate that is too low to be detected.

In some embodiments, where the substrate further comprises silicon nitride, the silicon nitride can be any suitable silicon nitride, many of which are known in the art. The chemical-mechanical polishing composition of the invention desirably exhibits a low removal rate of silicon nitride when polishing a substrate comprising silicon nitride according to a method of the invention. For example, when polishing substrates comprising silicon nitride in accordance with an embodiment of the invention, the polishing composition desirably exhibits a removal rate of silicon nitride of about 500 Å/min or lower, e.g., about 250 Å/min or lower, about 200 Å/min or lower, about 150 Å/min or lower, about 100 Å/min or lower, about 50 Å/min or lower, about 25 Å/min or lower, about 10 Å/min or lower, or about 5 Å/min or lower. In some embodiments, the polishing composition exhibits a silicon nitride removal rate that is too low to be detected.

In some embodiments, the substrate may be a carbon film. Examples of these carbon films may be grown using a variety of methods known in the art, including PECVD, spin-on, as well as others. The resulting films can have a wide range of properties (hardness, zeta potential, hydrophobicity, etc.). These carbon film substrates may be polished with the inventive formulations, for example formulation identical to the ones described in Example 3 of the instant invention, showing high removal rates. The slurries containing cerium ammonium nitrate and less than 0.1% solids are able to polish these films with high carbon removal rate and high selectivity to the underlying silicon oxide or silicon nitride films.

In some embodiments, where the substrate further comprises titanium nitride, the titanium nitride can be any suitable titanium nitride, many of which are known in the art. The chemical-mechanical polishing composition of the invention desirably exhibits a low removal rate of titanium nitride when polishing a substrate comprising titanium nitride according to a method of the invention. For example, when polishing substrates comprising titanium nitride in accordance with an embodiment of the invention, the polishing composition desirably exhibits a removal rate of titanium nitride of about 500 Å/min or lower, e.g., about 250 Å/min or lower, about 200 Å/min or lower, about 150 Å/min or lower, about 100 Å/min or lower, about 50 Å/min or lower, about 25 Å/min or lower, about 10 Å/min or lower, or about 5 Å/min or lower. In some embodiments, the polishing composition exhibits a titanium nitride removal rate that is too low to be detected.

The chemical-mechanical polishing composition of the invention can be tailored to provide effective polishing at the desired polishing ranges selective to specific thin layer materials, while at the same time minimizing surface imperfections, defects, corrosion, erosion, and the removal of stop layers. The selectivity can be controlled, to some extent, by altering the relative concentrations of the components of the polishing composition. When desirable, the chemical-mechanical polishing composition of the invention can be used to polish a substrate comprising boron-doped polysilicon and silicon oxide on a layer of the surface, wherein the chemical-mechanical polishing composition provides a boron-doped polysilicon to silicon oxide polishing selectivity of about 5:1 or higher (e.g., about 10:1 or higher, about 15:1 or higher, about 25:1 or higher, about 50:1 or higher, about 100:1 or higher, or about 150:1 or higher). Also, the chemical-mechanical polishing composition of the invention can be used to polish a substrate comprising boron-doped polysilicon and silicon nitride on a layer of the surface, wherein the chemical-mechanical polishing composition provides a boron-doped polysilicon to silicon nitride polishing selectivity of about 5:1 or higher (e.g., about 10:1 or higher, about 15:1 or higher, about 25:1 or higher, about 50:1 or higher, about 100:1 or higher, or about 150:1 or higher). In addition, the chemical-mechanical polishing composition of the invention can be used to polish a substrate comprising boron-doped polysilicon and titanium nitride on a layer of the surface, wherein the chemical-mechanical polishing composition provides a boron-doped polysilicon to titanium nitride polishing selectivity of about 5:1 or higher (e.g., about 10:1 or higher, about 15:1 or higher, about 25:1 or higher, about 50:1 or higher, about 100:1 or higher, or about 150:1 or higher). Thus, in embodiments, when used to polish substrates comprising at least one layer of boron-doped polysilicon and at least one layer of silicon oxide, at least one layer of silicon nitride, and/or at least one layer of titanium nitride, the polishing composition and polishing method allow for the preferential removal of boron-doped polysilicon as compared with the removal of silicon oxide, silicon nitride, and/or titanium nitride. As used herein, the phrase “polishing selectivity” refers to the ratio of the removal rates of two different thin layer materials.

The polishing composition of the invention desirably exhibits low particle defects when polishing a substrate, as determined by suitable techniques. Particle defects on a substrate polished with the inventive polishing composition can be determined by any suitable technique. For example, laser light scattering techniques, such as dark field normal beam composite (DCN) and dark field oblique beam composite (DCO), can be used to determine particle defects on polished substrates. Suitable instrumentation for evaluating particle defectivity is available from, for example, KLA-Tencor (e.g., SURFSCAN™ SPI instruments operating at a 120 nm threshold or at 160 nm threshold).

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof. Soft polyurethane polishing pads are particularly useful in conjunction with the inventive polishing method. Typical pads include but are not limited to SURFIN™ 000, SURFIN™ SSW1, SPM3100 (commercially available from, for example, Eminess Technologies), POLITEX™, EPIC™ D100 pad (commercially available from CMC Materials), IC1010 pad (commercially available from Dow, Inc.) and Fujibo POLYPAS™ 27.

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511. U.S. Pat. Nos. 5,643,046, 5,658,183, 5,730,642, 5,838,447, 5,872,633. U.S. Pat. Nos. 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

A substrate can be polished with any suitable downforce. For example, the substrate can be polishing with a downforce of about 1 psi or more, about 2 psi or more, about 3 psi or more, about 4 psi or more, or about 5 psi or more. Alternatively, or in addition, the substrate can be polished with a downforce of about 10 psi or less, about 8 psi or less, about 6 psi or less, about 4 psi or less, or about 2 psi or less. Thus, the substrate can be polished with a downforce bounded by any two of the aforementioned endpoints. For example, the substrate can be polished with a downforce of about 1 psi to about 10 psi, about 2 psi to about 10 psi, about 1 psi to about 8 psi, about 2 psi to about 8 psi, about 1 psi to about 6 psi, about 2 psi to about 6 psi, about 1 psi to about 4 psi, or about 2 psi to about 4 psi.

In some embodiments, the invention provides a method of chemically-mechanically polishing a substrate comprising: (i) providing a substrate, (ii) providing a polishing pad, (iii) providing a chemical-mechanical polishing composition comprising: (a) a silica abrasive; (b) at least 1 wt. % of a permanganate (e.g., potassium permanganate); and (c) water, wherein the chemical-mechanical polishing composition has a pH of about 2 or less, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate, wherein the substrate comprises a boron-doped polysilicon layer on a surface of the substrate, and wherein at least a portion of the boron-doped polysilicon layer on a surface of the substrate is abraded to polish the substrate.

In some embodiments, the invention provides a method of chemically-mechanically polishing a substrate comprising: (i) providing a substrate, (ii) providing a polishing pad, (iii) providing a chemical-mechanical polishing composition comprising: (a) a silica abrasive; (b) at least 1 wt. % of cerium ammonium nitrate; and (c) water, wherein the chemical-mechanical polishing composition has a pH of about 2 or less, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate, wherein the substrate comprises a boron-doped polysilicon layer on a surface of the substrate, and wherein at least a portion of the boron-doped polysilicon layer on a surface of the substrate is abraded to polish the substrate.

Aspects, including embodiments, of the invention described herein may be beneficial alone or in combination, with one or more other aspects or embodiments. Without limiting the foregoing description, certain non-limiting embodiments of the disclosure numbered 1-55 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

### EMBODIMENTS

(1) In embodiment (1) is presented a chemical-mechanical polishing composition comprising:
(a) a silica abrasive;
(b) an oxidizing agent; and
(c) water, wherein the chemical-mechanical polishing composition has a pH of about 2 or less.

(2) In embodiment (2) is presented the polishing composition of embodiment (1), wherein the polishing composition has a pH of about 1.5 or less.

(3) In embodiment (3) is presented the polishing composition of embodiment (1) or embodiment (2), wherein the polishing composition has a pH of about 1 or less.

(4) In embodiment (4) is presented the polishing composition of any one of embodiments (1)-(3), wherein the polishing composition comprises about 0.001 wt. % to about 10 wt. % of the silica abrasive.

(5) In embodiment (5) is presented the polishing composition of any one of embodiments (1)-(4), wherein the polishing composition comprises about 0.05 wt. % to about 5 wt. % of the silica abrasive.

(6) In embodiment (6) is presented the polishing composition of any one of embodiments (1)-(5), wherein the silica abrasive is colloidal silica.

(7) In embodiment (7) is presented the polishing composition of any one of embodiments (1)-(6), wherein the silica abrasive has an average particle size of about 25 nm to about 100 nm.

(8) In embodiment (8) is presented the polishing composition of any one of embodiments (1)-(7), wherein the silica abrasive has an average particle size of about 30 nm to about 75 nm.

(9) In embodiment (9) is presented the polishing composition of any one of embodiments (1)-(8), wherein the oxidizing agent is selected from oxone, cerium ammonium nitrate, a peroxide, a periodate, an iodate, a persulfate, a chlorate, a chromate, a permanganate, a bromate, a perbromate, a ferrate, a perrhenate, a perruthenate, and a combination thereof.

(10) In embodiment (10) is presented the polishing composition of any one of embodiments (1)-(9), wherein the oxidizing agent is selected from a permanganate, cerium ammonium nitrate, and a combination thereof.

(11) In embodiment (11) is presented the polishing composition of any one of embodiments (1)-(10), wherein the oxidizing agent is cerium ammonium nitrate.

(12) In embodiment (12) is presented the polishing composition of any one of embodiments (1)-(10), wherein the oxidizing agent is potassium permanganate.

(13) In embodiment (13) is presented the polishing composition of any one of embodiments (1)-(12), wherein the polishing composition comprises at least 1 wt. % of the oxidizing agent.

(14) In embodiment (14) is presented the polishing composition of any one of embodiments (1)-(13), wherein the polishing composition comprises at least 2 wt. % of the oxidizing agent.

(15) In embodiment (15) is presented the polishing composition of any one of embodiments (1)-(14), wherein the polishing composition comprises at least 3 wt. % of the oxidizing agent.

(16) In embodiment (16) is presented the polishing composition of any one of embodiments (1)-(15), wherein the polishing composition further comprises a ferric ion.

(17) In embodiment (17) is presented the polishing composition of embodiment (16), wherein the polishing composition comprises about 0.01 wt. % to about 1 wt. % of ferric ion.

(18) In embodiment (18) is presented the polishing composition of any one of embodiments (1)-(15), wherein the polishing composition comprises substantially no ferric ion.

(19) In embodiment (19) is presented the polishing composition of any one of embodiments (1)-(18), wherein the polishing composition further comprises an organic acid.

(20) In embodiment (20) is presented the polishing composition of embodiment (19), wherein the organic acid is selected from maleic acid, L-ascorbic acid, picolinic acid, malonic acid, and a combination thereof.

(21) In embodiment (21) is presented the polishing composition of embodiment (19) or embodiment (20), wherein the polishing composition comprises about 1 mM to about 100 mM of the organic acid.

(22) In embodiment (22) is presented the polishing composition of any one of embodiments (1)-(18), wherein the polishing composition comprises substantially no organic acid.

(23) In embodiment (23) is presented the polishing composition of any one of embodiments (1)-(22), wherein the polishing composition further comprises a buffering agent.

(24) In embodiment (24) is presented the polishing composition of embodiment (23), wherein the buffering agent is selected from an ammonium salt, an alkali metal salt, an alkali metal hydroxide, an alkali metal carbonate, an alkali metal bicarbonate, a borate, an amino acid, and a combination thereof.

(25) In embodiment (25) is presented a method of chemically-mechanically polishing a substrate comprising:
(i) providing a substrate,
(ii) providing a polishing pad,
(iii) providing a chemical-mechanical polishing composition comprising:
   (a) a silica abrasive;
   (b) an oxidizing agent; and
   (c) water,
   wherein the chemical-mechanical polishing composition has a pH of about 2 or less,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

(26) In embodiment (26) is presented the method of embodiment (25), wherein the polishing composition has a pH of about 1.5 or less.

(27) In embodiment (27) is presented the method of embodiment (25) or embodiment (26), wherein the polishing composition has a pH of about 1 or less.

(28) In embodiment (28) is presented the method of any one of embodiments (25)-(27), wherein the polishing composition comprises about 0.001 wt. % to about 10 wt. % of the silica abrasive.

(29) In embodiment (29) is presented the method of any one of embodiments (25)-(28), wherein the polishing composition comprises about 0.05 wt. % to about 5 wt. % of the silica abrasive.

(30) In embodiment (30) is presented the method of any one of embodiments (25)-(29), wherein the silica abrasive is colloidal silica.

(31) In embodiment (31) is presented the method of any one of embodiments (25)-(30), wherein the silica abrasive has an average particle size of about 25 nm to about 100 nm.

(32) In embodiment (32) is presented the method of any one of embodiments (25)-(31), wherein the silica abrasive has an average particle size of about 30 nm to about 75 nm.

(33) In embodiment (33) is presented the method of any one of embodiments (25)-(32), wherein the oxidizing agent is selected from oxone, cerium ammonium nitrate, a peroxide, a periodate, an iodate, a persulfate, a chlorate, a chromate, a permanganate, a bromate, a perbromate, a ferrate, a perrhenate, a perruthenate, and a combination thereof.

(34) In embodiment (34) is presented the method of any one of embodiments (25)-(33), wherein the oxidizing agent is selected from a permanganate, cerium ammonium nitrate, and a combination thereof.

(35) In embodiment (35) is presented the method of any one of embodiments (25)-(34), wherein the oxidizing agent is cerium ammonium nitrate.

(36) In embodiment (36) is presented the method of any one of embodiments (25)-(34), wherein the oxidizing agent is potassium permanganate.

(37) In embodiment (37) is presented the method of any one of embodiments (25)-(36), wherein the polishing composition comprises at least 1 wt. % of the oxidizing agent.

(38) In embodiment (38) is presented the method of any one of embodiments (25)-(37), wherein the polishing composition comprises at least 2 wt. % of the oxidizing agent.

(39) In embodiment (39) is presented the method of any one of embodiments (25)-(38), wherein the polishing composition comprises at least 3 wt. % of the oxidizing agent.

(40) In embodiment (40) is presented the method of any one of embodiments (25)-(39), wherein the polishing composition further comprises a ferric ion.

(41) In embodiment (41) is presented the method of embodiment (40), wherein the polishing composition comprises about 0.01 wt. % to about 1 wt. % of ferric ion.

(42) In embodiment (42) is presented the method of any one of embodiments (25)-(39), wherein the polishing composition comprises substantially no ferric ion.

(43) In embodiment (43) is presented the method of any one of embodiments (25)-(42), wherein the polishing composition further comprises an organic acid.

(44) In embodiment (44) is presented the method of embodiment (43), wherein the organic acid is selected from maleic acid, L-ascorbic acid, picolinic acid, malonic acid, and a combination thereof.

(45) In embodiment (45) is presented the method of embodiment (43) or embodiment (44), wherein the polishing composition comprises about 1 mM to about 100 mM of the organic acid.

(46) In embodiment (46) is presented the method of any one of embodiments (25)-(42), wherein the polishing composition comprises substantially no organic acid.

(47) In embodiment (47) is presented the method of any one of embodiments (25)-(46), wherein the polishing composition further comprises a buffering agent.

(48) In embodiment (48) is presented the method of embodiment (47), wherein the buffering agent is selected from an ammonium salt, an alkali metal salt, an alkali metal hydroxide, an alkali metal carbonate, an alkali metal bicarbonate, a borate, an amino acid, and a combination thereof.

(49) In embodiment (49 is presented the method of any one of embodiments (25)-(48), wherein the substrate comprises a boron-doped polysilicon layer on a surface of the substrate, and wherein at least a portion of the boron-doped polysilicon layer on a surface of the substrate is abraded to polish the substrate.

(50) In embodiment (50) is presented the method of embodiment (49), wherein the boron-doped polysilicon layer comprises at least 80 wt. % boron.

(51) In embodiment (51) is presented the method of embodiment (49), wherein the boron-doped polysilicon layer comprises at least 85 wt. % boron.

(52) In embodiment (52) is presented the method of embodiment (49), wherein the boron-doped polysilicon layer comprises at least 90 wt. % boron.

(53) In embodiment (53) is presented the method of any one of embodiments (49)-(52), wherein the substrate further comprises a silicon nitride layer on a surface of the substrate, and wherein at least a portion of the silicon nitride layer on the surface of the substrate is abraded to polish the substrate.

(54) In embodiment (54) is presented the method of embodiment (53), wherein the chemical-mechanical polishing composition provides a boron-doped polysilicon to silicon nitride polishing selectivity of about 5:1 or higher.

(55) In embodiment (55) is presented the method of any one of embodiments (49)-(54), wherein the substrate further comprises a silicon oxide layer on a surface of the substrate, and wherein at least a portion of the silicon oxide layer on a surface of the substrate is abraded to polish the substrate.

(56) In embodiment (56) is presented the method of embodiment (55), wherein the chemical-mechanical polishing composition provides a boron-doped polysilicon to silicon oxide polishing selectivity of about 5:1 or higher.

(57) In embodiment (57) is presented the method of any one of embodiments (49)-(56), wherein the substrate further comprises a titanium nitride layer on a surface of the substrate, and wherein at least a portion of the titanium nitride layer on a surface of the substrate is abraded to polish the substrate.

(58) In embodiment (58) is presented the method of embodiment (57), wherein the chemical-mechanical polishing composition provides a boron-doped polysilicon to titanium nitride polishing selectivity of about 5:1 or higher.

### EXAMPLES

These following examples further illustrate the invention but, of course, should not be construed as in any way limiting its scope.

The following abbreviations are used throughout the Examples: removal rate (RR); boron-doped polysilicon (BSi); tetraethyl orthosilicate (TEOS); weight percentage (wt. %), and pounds per square inch (psi).

### Example 1

This example demonstrates the effect of polishing promoter (e.g., oxidizing agent) on the polishing performance of a polishing composition prepared according to the invention.

Polishing Compositions 1A-1L contained 2 wt. % of a cationic silica particle having an average particle size of approximately 45 nm, 43.77 mM of each polishing promoter (i.e., oxidizing agent and/or additive), a biocide (PROXEL™ AQ), and each had a pH of approximately 1.5. The oxidizing agents and additives are set forth in Table 1.

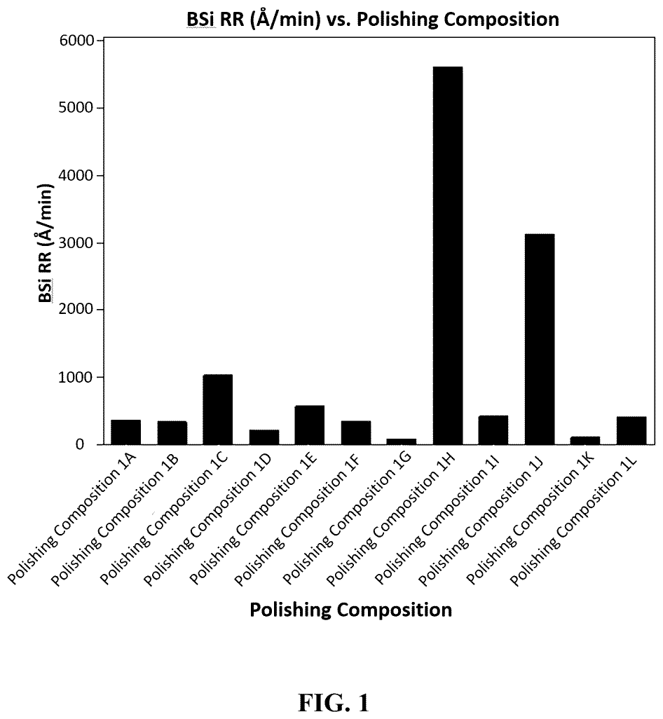

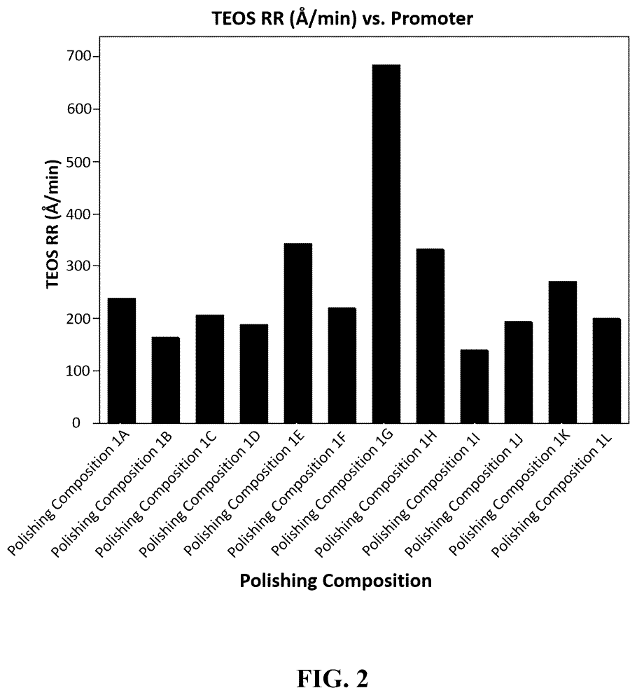

Patterned substrates comprising TEOS or a boron-doped polysilicon (BSi) layer comprising approximately 95 wt. % boron coated on wafers were polished with Polishing Compositions 1A-1L, as defined in Table 1, using a REFLEXION™ (Applied Materials, Inc.) polishing tool at 3 PSI (20.55 kPa) downforce using a NexPlanar U5890 pad (CMC Materials Inc.) conditioned with a product commercially identified as SAESOL™ DS8051 (SAESOL Diamond Ind. Co. Ltd.). REFLEXION™ polishing parameters were as follows: headspeed=87 rpm, platen speed=98 rpm, total flow rate=50 mL/min. TEOS patterned substrates were polished for 30 seconds and BSi patterned substrates were polished for 15 seconds. Removal rates were calculated by measuring the film thickness, using spectroscopic elipsometry, and subtracting the final thickness from the initial thickness. The results are set forth in Table 1 and plotted in FIGS. 1 and 2. The selectivity (Å/min) in Table 1 refers to the polishing rate of BSi relative to the polishing rate of TEOS.

TABLE 1
Polishing Composition Removal Rates
as a Function of Oxidizing Agent

| Polishing | Oxidizing | | BSi | TEOS | Selectivity |
|---|---|---|---|---|---|
| Composition | Agent | Additive | (Å/min) | (Å/min) | (Å/min) |
| 1A | Peroxide | Co(III) | 363 | 239 | 1.5:1 |
| | | acetate | | | |
| 1B | none | Fe(III) | 338 | 164 | 2:1 |
| | | nitrate | | | |
| 1C | Periodate | Fe(III) | 1033 | 207 | 5:1 |
| | | nitrate | | | |
| 1D | Peroxide | Fe(III) | 217 | 189 | 1.1:1 |
| | | nitrate | | | |
| 1E | Potassium | Fe(III) | 570 | 344 | 1.7:1 |
| | Persulfate | nitrate | | | |
| 1F | Iodate | none | 345 | 220 | 1.6:1 |
| 1G | none | Mn(III) | 86 | 685 | 0.1:1 |
| | | acetate | | | |
| 1H | CAN | none | 5617 | 333 | 16.9:1 |
| 1I | Periodate | none | 427 | 140 | 3:1 |
| 1J | Potassium | none | 3123 | 194 | 16.1:1 |
| | Permanganate | | | | |
| 1K | Potassium | none | 109 | 271 | 0.4:1 |
| | Persulfate | | | | |
| 1L | Persulfate and | none | 417 | 200 | 2.1:1 |
| | Periodate | | | | |

As is apparent from the results set forth in Table 1 and FIGS. 1 and 2, Polishing Compositions 1C, 1H, and 1J, comprising periodate, cerium ammonium nitrate (CAN), and potassium permanganate, respectively, provided the highest BSi removal rates. In addition, Table 1 shows that Polishing Compositions 1H and 1J, comprising cerium ammonium nitrate (CAN) and potassium permanganate, respectively, exhibited the best BSi to TEOS selectivity at approximately 16:1. Thus, Table 1 and FIGS. 1 and 2 show that the addition of oxidizing agents such as periodate, cerium ammonium nitrate (CAN), and potassium permanganate increases the BSi removal rate while maintaining low TEOS removal rates.

### Example 2

This example demonstrates the effect of the type and size of abrasive particle on the polishing performance of polishing compositions prepared according to the invention.

Polishing compositions containing 2 wt. % of anionic, cationic, or neutral silica particles having different average particle sizes were prepared as set forth in Table 2. The polishing compositions further contained 43.77 mM of cerium ammonium nitrate, a biocide (PROXEL™ AQ), and each had a pH of approximately 1.5.

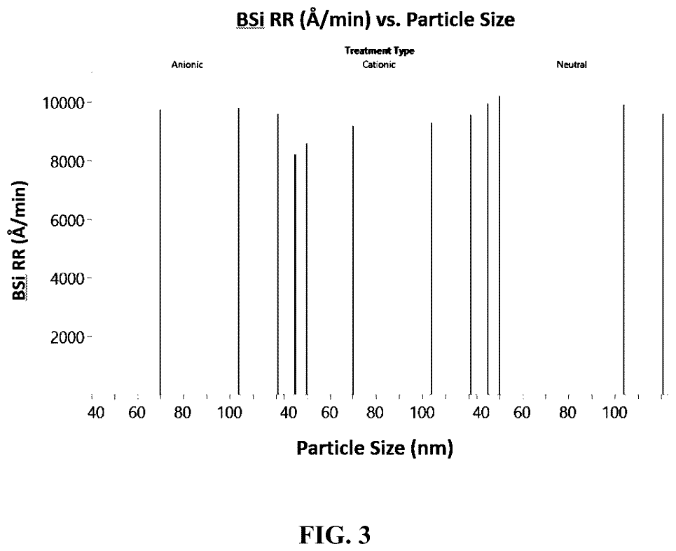

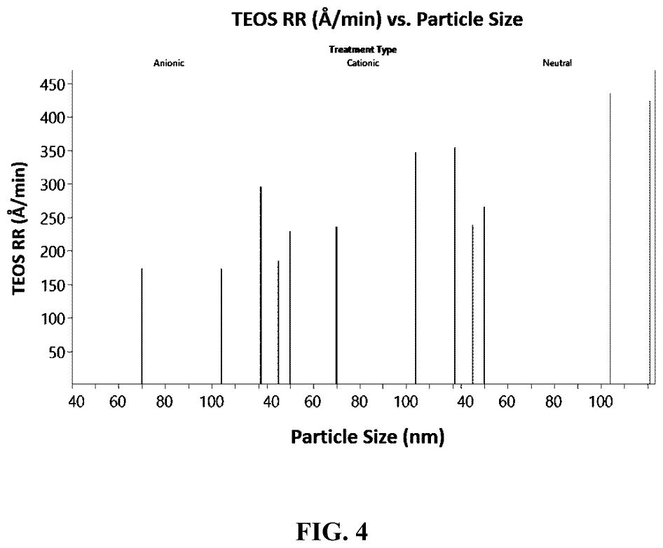

Patterned substrates comprising TEOS or a boron-doped polysilicon (BSi) layer comprising approximately 95 wt. % boron coated on wafers were polished with polishing compositions containing the particles described in Table 2, using a REFLEXION™ (Applied Materials, Inc.) polishing tool at 3 PSI (20.55 kPa) downforce using a NexPlanar U5890 pad conditioned with a product commercially identified as SAESOL™ DS8051. REFLEXION™ polishing parameters were as follows: headspeed=87 rpm, platen speed=93 rpm, total flow rate=50 m/min. TEOS patterned substrates were polished for 30 seconds and BSi patterned substrates were polished for 15 seconds. Removal rates were calculated by measuring the film thickness, using spectroscopic elipsometry, and subtracting the final thickness from the initial thickness. The results are set forth in Table 2 and plotted in FIGS. 3 and 4. The selectivity (Å/min) in Table 2 refers to the polishing rate of BSi relative to the polishing rate of TEOS.

TABLE 2
Polishing Composition Removal Rates as a Function
of Type and Size of Abrasive Particle

| | Particle Size | BSi | TEOS | Selectivity |
|---|---|---|---|---|
| Particle Type | (nm) | (Å/min) | (Å/min) | (Å/min) |
| Anionic | 70 | 9750 | 174 | 56:1 |
| Anionic | 104 | 9794 | 173 | 57:1 |
| Anionic | 121 | 9597 | 296 | 32:1 |
| Cationic | 45 | 8209 | 185 | 44:1 |
| Cationic | 50 | 8588 | 229 | 38:1 |
| Cationic | 70 | 9181 | 236 | 39:1 |
| Cationic | 104 | 9297 | 347 | 27:1 |
| Cationic | 121 | 9574 | 355 | 27:1 |
| Neutral | 45 | 9949 | 239 | 42:1 |
| Neutral | 50 | 10208 | 266 | 38:1 |
| Neutral | 104 | 9908 | 435 | 23:1 |
| Neutral | 121 | 9601 | 424 | 23:1 |

As is apparent from the results set forth in Table 2 and FIGS. 3 and 4, anionic particle, cationic particles, and neutral particles all provide high BSi removal rates while maintaining low TEOS removal rates. In addition, Table 2 shows that as particle size decreases for each of the particle types (i.e., anionic, cationic, and neutral), the selectivity for removing BSi relative to TEOS increases. Thus, Table 2 and FIGS. 3 and 4 show that anionic particles, cationic particles, and neutral particles are suitable for high BSi removal rates and that smaller particle sizes may help improve BSi selectivity with respect to TEOS.

### Example 3

This example demonstrates the effect of the type and amount of abrasive particle and the downforce on the polishing performance of polishing compositions prepared according to the invention.

Polishing compositions containing 2 wt. % of cationic or neutral silica particles having an average particle size of approximately 45 nm were prepared with the amounts set forth in Table 3. The polishing compositions further contained 43.77 mM of cerium ammonium nitrate, a biocide (PROXEL™ AQ), and each had a pH of approximately 1.5.

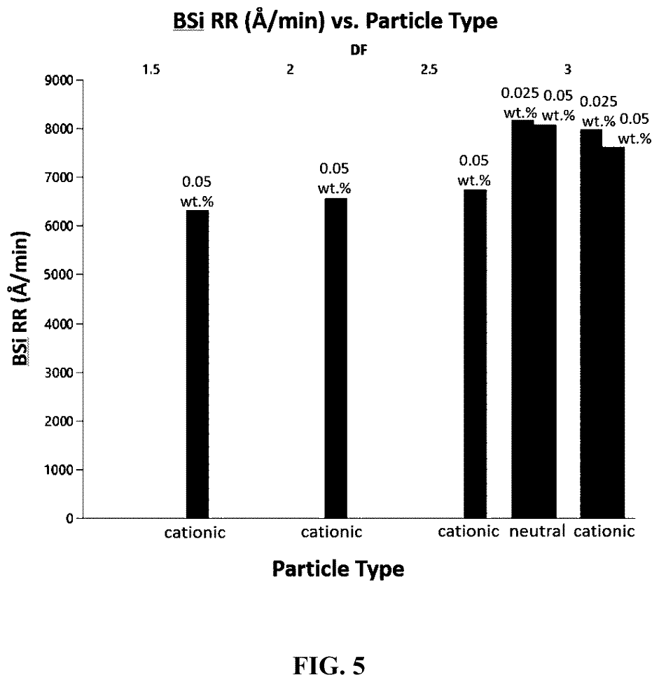

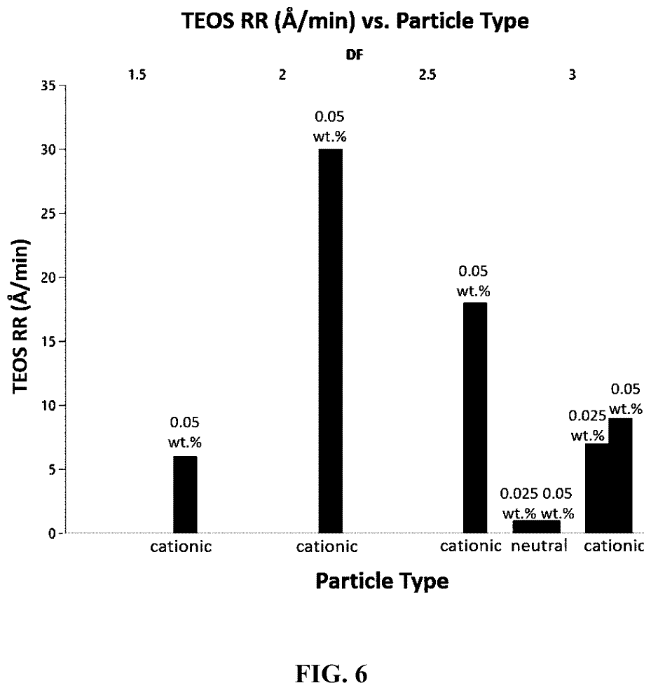

Patterned substrates comprising TEOS or a boron-doped polysilicon (BSi) layer comprising approximately 95 wt. % boron coated on wafers were polished with polishing compositions containing the particles described in Table 3, using a REFLEXION™ (Applied Materials, Inc.) polishing tool at the downforces provided in Table 3 using a NexPlanar U5890 pad conditioned with a product commercially identified as SAESOL™ DS8051. REFLEXION™ polishing parameters were as follows: headspeed=87 rpm, platen speed=98 rpm, total flow rate=50 mL/min. TEOS patterned substrates were polished for 30 seconds and BSi patterned substrates were polished for 15 seconds. Removal rates were calculated by measuring the film thickness, using spectroscopic elipsometry, and subtracting the final thickness from the initial thickness. The results are set forth in Table 3 and plotted in FIGS. 5 and 6. The selectivity (Å/min) in Table 2 refers to the polishing rate of BSi relative to the polishing rate of TEOS.

TABLE 3
Polishing Composition Removal Rates as a Function of
Type and Amount of Abrasive Particle and Downforce

| | Amount | Downforce | BSi | TEOS | Selectivity |
|---|---|---|---|---|---|
| Particle Type | (wt. %) | (psi) | (Å/min) | (Å/min) | (Å/min) |
| Cationic | 0.05 | 1.5 | 6317 | 6 | 1053:1 |
| Cationic | 0.05 | 2 | 6557 | 30 | 219:1 |
| Cationic | 0.05 | 2.5 | 6747 | 18 | 375:1 |
| Neutral | 0.025 | 3 | 8171 | 1 | 8171:1 |
| Neutral | 0.05 | 3 | 8079 | 1 | 8079:1 |
| Cationic | 0.025 | 3 | 7978 | 7 | 1140:1 |
| Cationic | 0.05 | 3 | 7615 | 9 | 846:1 |

As is apparent from the results set forth in Table 3 and FIGS. 5 and 6, lowering the polishing downforce to as low as 1.5 psi and the particle amount as low as 0.025 wt. % provides high BSi removal rates (e.g., greater than 6000 Å/min) and decreases the TEOS removal rate to below 30 Å/min, including to as low as 1 Å/min. In other words, by decreasing the polishing downforce and reducing the particle loading, the selectivity for removing BSi relative to TEOS can be increased significantly. Thus, Table 3 and FIGS. 5 and 6 show that polishing compositions comprising a silica abrasive, an oxidizing agent (e.g., cerium ammonium nitrate), and a pH of about 2 or less provide high BSi removal rates and high BSi selectivity with respect to TEOS over a variety of polishing parameters.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) about 0.001 wt. % to about 10 wt. % of a silica abrasive;
(b) an oxidizing agent selected from oxone, cerium ammonium nitrate, a peroxide, a periodate, an iodate, a persulfate, a chlorate, a chromate, a permanganate, a bromate, a perbromate, a ferrate, a perrhenate, a perruthenate, and a combination thereof; and
(c) water,
wherein the chemical-mechanical polishing composition has a pH of about 2 or less.

2. The polishing composition of claim 1, wherein the polishing composition has a pH of about 1.5 or less.

3. The polishing composition of claim 1, wherein the polishing composition has a pH of about 1 or less.

4. The polishing composition of claim 1, wherein the polishing composition comprises about 0.025 wt. % to about 5 wt. % of the silica abrasive.

5. The polishing composition of claim 1, wherein the silica abrasive has an average particle size of about 25 nm to about 100 nm.

6. The polishing composition of claim 1, wherein the silica abrasive has an average particle size of about 30 nm to about 75 nm.

7. The polishing composition of claim 1, wherein the oxidizing agent is selected from a permanganate, cerium ammonium nitrate, and a combination thereof.

8. The polishing composition of claim 7, wherein the oxidizing agent is cerium ammonium nitrate.

9. The polishing composition of claim 1, wherein the polishing composition comprises at least 1 wt. % of the oxidizing agent.

10. The polishing composition of claim 1, wherein the polishing composition further comprises about 0.01 wt. % to about 1 wt. % of a ferric ion.

11. The polishing composition of claim 1, wherein the polishing composition further comprises an organic acid.

12. The polishing composition of claim 11, wherein the organic acid is selected from maleic acid, L-ascorbic acid, picolinic acid, malonic acid, and a combination thereof.

13. The polishing composition of claim 12, wherein the polishing composition comprises about 1 mM to about 100 mM of the organic acid.

14. The polishing composition of claim 1, wherein the polishing composition further comprises a buffering agent.

15. A method of chemically-mechanically polishing a substrate comprising:
(i) providing a substrate,
(ii) providing a polishing pad,
(iii) providing a chemical-mechanical polishing composition comprising:
(a) about 0.001 wt. % to about 10 wt. % of a silica abrasive;
(b) an oxidizing agent selected from oxone, cerium ammonium nitrate, a peroxide, a periodate, an iodate, a persulfate, a chlorate, a chromate, a permanganate, a bromate, a perbromate, a ferrate, a perrhenate, a perruthenate, and a combination thereof; and
(c) water,
wherein the chemical-mechanical polishing composition has a pH of about 2 or less,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

16. The method of claim 15, wherein the substrate comprises a boron-doped polysilicon layer on a surface of the substrate, and wherein at least a portion of the boron-doped polysilicon layer on a surface of the substrate is abraded to polish the substrate.

17. The method of claim 17, wherein the boron-doped polysilicon layer comprises at least 80 wt. % boron.

18. The method of claim 18, wherein the boron-doped polysilicon layer comprises at least 90 wt. % boron.

19. The method of claim 15, wherein the substrate further comprises a silicon nitride layer on a surface of the substrate, and wherein at least a portion of the silicon nitride layer on the surface of the substrate is abraded to polish the substrate.

20. The method of claim 15, wherein the substrate further comprises a silicon oxide layer on a surface of the substrate, and wherein at least a portion of the silicon oxide layer on a surface of the substrate is abraded to polish the substrate.
